(19) United States
(12) Patent Application Publication
(10) Pub. No.: US 2026/0136564 A1
(43) Pub. Date: May 14, 2026

(54) SEMICONDUCTOR DIE STACK, SEMICONDUCTOR PACKAGE INCLUDING THE SAME AND METHOD FOR MANUFACTURING THE SAME

(71) Applicant: SAMSUNG ELECTRONICS CO., LTD., Suwon-si (KR)

(72) Inventors: Byeongguk KO, Suwon-s (KR); KYUNGSEOK OH, Suwon-si (KR); GiTae MOON, Suwon-si (KR); Seonghyeon PARK, Suwon-si (KR); JAE-WHA PARK, Suwon-si (KR); EUNSUK JUNG, Suwon-si (KR)

(73) Assignee: SAMSUNG ELECTRONICS CO., LTD., Suwon-si (KR)

(21) Appl. No.: 19/210,668

(22) Filed: May 16, 2025

(30) Foreign Application Priority Data
Nov. 13, 2024 (KR) 10-2024-0161407

(51) Int. Cl. H01L 23/00; H01L 25/18; H10B 80/00

(52) U.S. Cl. CPC H10B 80/00; H10W 90/00; H10W 72/019; H10W 72/953; H10W 80/016; H10W 80/312; H10W 80/327; H10W 90/792

(57) ABSTRACT

A semiconductor die stack includes a first semiconductor die and a second semiconductor die. The first semiconductor die includes a first die base and a first bonding structure on the first die base. The first bonding structure includes: a first dielectric layer including a first lower dielectric layer and a first upper dielectric layer on the first lower dielectric layer, and including a silicon compound; and a plurality of first bonding pad extending through the first dielectric layer, the first lower dielectric layer including a first content of silicon per unit volume, the first upper dielectric layer including a second content of silicon per unit volume, and the second content per unit volume being greater than the first content per unit volume.

### CROSS-REFERENCE TO RELATED APPLICATION

This application claims priority to and the benefit of Korean Patent Application No. 10-2024-0161407 filed with the Korean Intellectual Property Office on Nov. 13, 2024, the disclosure of which is herein incorporated by reference in its entirety.

### BACKGROUND

### 1. Field

One or more example embodiments of the disclosure relate to a semiconductor die stack, a semiconductor package including the semiconductor die stack, and a method for manufacturing the semiconductor die stack.

### 2. Description of Related Art

In a semiconductor industry, there is a demand for a semiconductor package mounted in an electronic device that is miniaturized, lightweight, and thinned, while at the same time, having high-speed, multifunction, and large-capacity, in line with a demand for miniaturization and light weight of electronic devices. Thus, a need for packaging technology that can store more data and transmit data at a higher speed is increasing. Accordingly, a stacked semiconductor device (e.g., a high bandwidth memory (HBM)), which is formed by stacking a plurality of individual semiconductor chips, is being developed.

Stacked semiconductor devices are manufactured by combining same type or different type semiconductor chips, it is important that the semiconductor chips are combined with a high input/output (I/O) density. If the I/O density is increased and an electrical signal connection density becomes similar to a wiring density in a semiconductor front end process, even if same type or different type semiconductor chips are combined in a semiconductor back end process, similar results may be produced as a single semiconductor chip made through the semiconductor front end process.

In this way, in order to manufacture bonded semiconductor chips with a high I/O density, a hybrid bonding process may be applied to bond between semiconductor chips. The hybrid bonding is to bond two devices by fusing a same material included in the two devices using a bonding property of the same material. Herein, hybrid indicates that two different types of bonding are made, e.g., bonding two devices with a first type of metal-to-metal bonding and a second type of dielectric-to-dielectric bonding.

In the hybrid bonding, the dielectric-to-dielectric bonding is achieved by activating bonding surfaces of respective dielectrics using plasma and then covalently bonding the activated bonding surfaces of the dielectrics. In this case, the bonding surfaces of metals exposed between the dielectrics may also be affected by a plasma process, and the metals affected by the plasma may remain in a chamber where the plasma process is performed and contaminate the chamber. In addition, when using plasma from an oxygen source series or a nitrogen source series, metal oxidation or nitridation may occur.

In addition, when a dielectric material is deposited using SiCN, as a content of carbon in the dielectric is high, the bonding surface of the dielectric may be better activated and a bonding strength between the dielectrics may be improved during the plasma process. However, the carbon content within the dielectric may not be further controlled after the dielectric is deposited. Thus, a new method is needed to enhance the bonding strength between the dielectrics.

### SUMMARY

One or more example embodiments of the disclosure provide a semiconductor die stack including a bonding structure in which an additional dielectric is formed by supplying a dielectric source on a bonding surface of the dielectric, and a semiconductor package including the semiconductor die stack.

According to an aspect of an example embodiment of the present disclosure, provided is a semiconductor die stack including: a first semiconductor die including a first die base and a first bonding structure on the first die base, wherein the first bonding structure includes: a first dielectric layer including a first lower dielectric layer and a first upper dielectric layer on the first lower dielectric layer, the first dielectric layer including a silicon compound; and a plurality of first bonding pads extending through the first dielectric layer, the first lower dielectric layer including a first content of silicon per unit volume, the first upper dielectric layer including a second content of silicon per unit volume, and the second content per unit volume being greater than the first content per unit volume; and a second semiconductor die including a second die base and a second bonding structure on the second die base, wherein the second bonding structure includes: a second dielectric layer including a second lower dielectric layer and a second upper dielectric layer on the second lower dielectric layer, the second dielectric layer including a silicon compound; and a plurality of second bonding pads extending through the second dielectric layer, the second lower dielectric layer including a third content of silicon per unit volume, the second upper dielectric layer including a fourth content of silicon per unit volume, the fourth content per unit volume being greater than the third content per unit volume, the first dielectric layer being bonded to the second dielectric layer, and each first bonding pad among the plurality of first bonding pads being bonded to a corresponding second bonding pad among the plurality of second bonding pads.

According to an aspect of an example embodiment of the present disclosure, provided is a semiconductor package including: a base die; a semiconductor die stack including a plurality of semiconductor dies vertically stacked on the base die; and a molding material on at least one surface of the semiconductor die stack on the base die, wherein each of the plurality of semiconductor dies includes: a die base including a front side and a back side; a front side bonding structure disposed on the front side of the die base, the front side bonding structure including a front side dielectric layer including a silicon compound and a plurality of front side bonding pads extending through the front side dielectric layer; and a back side bonding structure disposed on the back side of the die base, the back side bonding structure including a back side dielectric layer including a silicon compound and a plurality of back side bonding pads extending through the back side dielectric layer, wherein each of the front side dielectric layer and the back side dielectric layer includes: a lower dielectric layer including a first content of silicon per unit volume; and an upper dielectric layer including a second content per unit volume of silicon that is greater than the first content per unit volume, a front side dielectric layer of each semiconductor die among the plurality of semiconductor dies is bonded to a back side dielectric layer of a neighboring semiconductor die, and each front side bonding pad among a plurality of front side bonding pads of each semiconductor die among the plurality of semiconductor dies is bonded to a corresponding back side bonding pad among a plurality of back side bonding pads of a neighboring semiconductor die.

According to an aspect of an example embodiment of the present disclosure, provided is a method for manufacturing a semiconductor die stack including: depositing a first lower dielectric layer including a silicon compound on a first wafer, and depositing a second lower dielectric layer including a silicon compound on a second wafer; forming a plurality of first bonding pads in the first lower dielectric layer and forming a plurality of second bonding pads in the second lower dielectric layer; adsorbing an inhibitor on the plurality of first bonding pads and on the plurality of second bonding pads; forming a first upper dielectric layer by supplying a silicon compound to the first lower dielectric layer and forming a second upper dielectric layer by supplying a silicon compound to the second lower dielectric layer, wherein the first lower dielectric layer includes a first content of silicon per unit volume, the first upper dielectric layer includes a second content of silicon per unit volume that is greater than the first content per unit volume, the second lower dielectric layer includes a third content of silicon per unit volume, and the second upper dielectric layer includes a fourth content of silicon per unit volume that is greater than the third content per unit volume; activating a surface of the first upper dielectric layer by plasma, and activating a surface of the second upper dielectric layer by plasma; cleaning the surface of the first upper dielectric layer and cleaning the surface of the second upper dielectric layer; and bonding the first upper dielectric layer of the first wafer and the second upper dielectric layer of the second wafer.

### BRIEF DESCRIPTION OF DRAWINGS

Example embodiments of the disclosure will be more clearly understood from the following detailed description taken in conjunction with the accompanying diagrams.

FIG. 1 illustrates a cross-sectional view showing a semiconductor die stack according to one or more embodiments.

FIG. 2 to FIG. 11 illustrate cross-sectional views for describing a manufacturing method for the semiconductor die stack according to the one or more embodiments of FIG. 1.

FIG. 12 illustrates a cross-sectional view showing a semiconductor package including a semiconductor die stack according to one or more embodiments.

### DETAILED DESCRIPTION

The present disclosure will be described more fully hereinafter with reference to the accompanying drawings, in which example embodiments of the disclosure are shown. As those skilled in the art would realize, the described embodiments may be modified in various different ways, all without departing from the spirit or scope of the present disclosure.

To clearly describe the present disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Hereinafter, a semiconductor die stack 100 of an embodiment, a manufacturing method for the semiconductor die stack 100, and a semiconductor package 200 including the semiconductor die stack 100 according to one or more embodiments will be described with reference to the drawings.

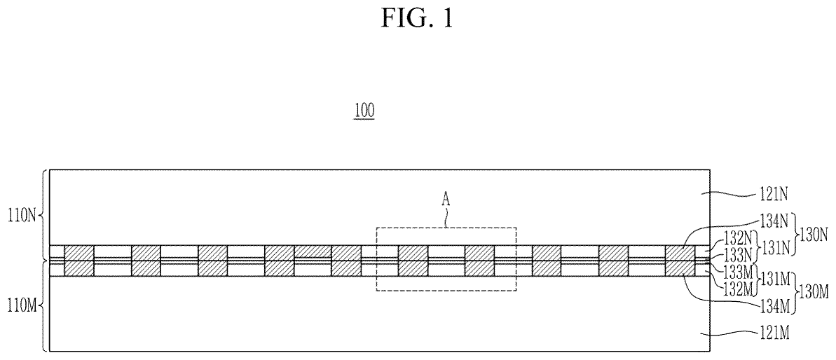

FIG. 1 illustrates a cross-sectional view showing the semiconductor die stack 100 according to according to one or more embodiments.

Referring to FIG. 1, the semiconductor die stack 100 may include a first semiconductor die 110M and a second semiconductor die 110N. The first semiconductor die 110M and the second semiconductor die 110N may be bonded to each other by hybrid bonding to form the semiconductor die stack 100. The first semiconductor die 110M and the second semiconductor die 110N may be same type dies or different type dies. In FIG. 1, it is illustrated that the first semiconductor die 110M and the second semiconductor die 110M constitute the semiconductor die stack 100, but the present disclosure is not limited thereto, and the semiconductor die stack 100 may include three or more semiconductor dies 110.

When the first semiconductor die 110M and the second semiconductor die 110N are same type dies, the first semiconductor die 110M and the second semiconductor die 110N may include a same configuration. In an embodiment, the first semiconductor die 110M and the second semiconductor die 110N may each include a memory die. In an embodiment, the first semiconductor die 110M and the second semiconductor die 110N may each include a dynamic random-access memory (DRAM).

When the first semiconductor die 110M and the second semiconductor die 110N are different type dies, the first semiconductor die 110M and the second semiconductor die 110N may include different configurations. In an embodiment, the first semiconductor die 110M may include a logic die, and the second semiconductor die 110N may include a memory die. In an embodiment, the first semiconductor die 110M may include a system on chip (SoC) or an application processor (AP), and the second semiconductor die 110N may include a DRAM. In an embodiment, the first semiconductor die 110M and the second semiconductor die 110N may each include a chiplet formed by dividing a logic die.

The first semiconductor die 110M may include a first die base 121M and a first bonding structure 130M. The second semiconductor die 110N may include a second die base 121N and a second bonding structure 130N. The first die base 121M may include a front side and a back side, which is an opposite side of the front side. The first die base 121M may be a die formed from a wafer. In an embodiment, the first die base 121M may include silicon or other semiconductor materials.

A front side structure may be positioned on the front side of the first die base 121M. The front side structure may include a device layer and a wiring layer. The device layer may be disposed on the front side of the first die base 121M. The device layer may include an integrated circuit structure having integrated circuit regions. In an embodiment, the integrated circuit structure may include at least one of an active device or a passive device. In an embodiment, the integrated circuit structure may include a gate structure, a source region, and a drain region. In an embodiment, the integrated circuit structure may include at least one of a transistor, a diode, a capacitor, an inductor, or a resistor. The wiring layer may be disposed on the device layer. The wiring layer may include a signal wiring line(s), a power wiring line(s), a contact plug(s), and an inter metal dielectric (IMD).

The first bonding structure 130M may be positioned on the front side structure on the front side of the first die base 121M or on the back side of the first die base 121M. The first bonding structure 130M may include a first dielectric layer 131M and first bonding pads 134M. The first dielectric layer 131M may be bonded to a second dielectric layer 131N of the second semiconductor die 110N by performing dielectric-to-dielectric hybrid bonding. The second dielectric layer 131N may include a second lower dielectric layer 132N and a second upper dielectric layer 133N. The second upper dielectric layer 133N may be disposed on the second lower dielectric layer 132N. The first dielectric layer 131M may include a silicon compound. In an embodiment, the first dielectric layer 131M may include a silicon oxide or a silicon nitride. In an embodiment, the first dielectric layer 131M may include SiO₂ or SiCN. In an embodiment, a thickness of the first dielectric layer 131M in a vertical direction may be in a range of about 0.1 μm to about 8 μm.

The first dielectric layer 131M may include a first lower dielectric layer 132M and a first upper dielectric layer 133M. The first upper dielectric layer 133M may be disposed on the first lower dielectric layer 132M. The first lower dielectric layer 132M and the first upper dielectric layer 133M may include a same silicon compound. In an embodiment, the first lower dielectric layer 132M and the first upper dielectric layer 133M may include a same silicon oxide or a same silicon nitride. The first lower dielectric layer 132M may have a first thickness in the vertical direction. The first upper dielectric layer 133M may have a second thickness in the vertical direction. The second thickness may be less than the first thickness. In an embodiment, a thickness of the first lower dielectric layer 132M in the vertical direction may be in a range of about 0.1 μm to about 8 μm. In an embodiment, a thickness of the first upper dielectric layer 133M in the vertical direction may be in a range of about 0.5 nm to about 5 nm.

The first lower dielectric layer 132M and the first upper dielectric layer 133M may include SiO₂. The first lower dielectric layer 132M may include a first content of silicon per unit volume. The first upper dielectric layer 133M may include a second content of silicon per unit volume. The second content per unit volume may be greater than the first content per unit volume. An oxygen content per unit volume of the first upper dielectric layer 133M may be greater than an oxygen content per unit volume of the first lower dielectric layer 132M.

The first lower dielectric layer 132M and the first upper dielectric layer 133M may include SiCN. The first lower dielectric layer 132M may include a first content of silicon per unit volume. The first upper dielectric layer 133M may include a second content of silicon per unit volume. The second content per unit volume may be greater than the first content per unit volume. An oxygen content per unit volume of the first upper dielectric layer 133M may be greater than an oxygen content per unit volume of the first lower dielectric layer 132M. A carbon content per unit volume of the first upper dielectric layer 133M may be greater than a carbon content per unit volume of the first lower dielectric layer 132M. A nitrogen content per unit volume of the first upper dielectric layer 133M may be greater than a nitrogen content per unit volume of the first lower dielectric layer 132M.

The first bonding pads 134M may extend through the first dielectric layer 131M. The first bonding pads 134M may extend through the first lower dielectric layer 132M and the first upper dielectric layer 133M. The first bonding pads 134M may be bonded to second bonding pads 134N of the second semiconductor die 110N by performing metal-to-metal hybrid bonding. The second bonding pads 134N may extend through the second dielectric layer 131N. The second bonding pads 134N may extend through the second lower dielectric layer 132N and the second upper dielectric layer 133N. An electrical connection may be established between the first semiconductor die 110M and the second semiconductor die 110N by this metal-to-metal hybrid bonding. A level of bonding surfaces of the first bonding pads 134M may be the same as a level of a bonding surface of the first dielectric layer 131M. Side surfaces of the first bonding pads 134M may be surrounded by the first lower dielectric layer 132M and the first upper dielectric layer 133M. In an embodiment, a width of the first pads 134M in a horizontal direction may be about 0.01 μm to about 30 μm. In an embodiment, a depth of the first pads 134M in the vertical direction may be about 0.1 μm to about 8 μm.

The second semiconductor die 110N may be bonded to the first semiconductor die 110M by hybrid bonding. The description for the first semiconductor die 110M may be applied to the second semiconductor die 110N. Specifically, in the description of the first semiconductor die 110M, changing “first” to “second”, “M”, and “N” may be applied to the second semiconductor die 110N.

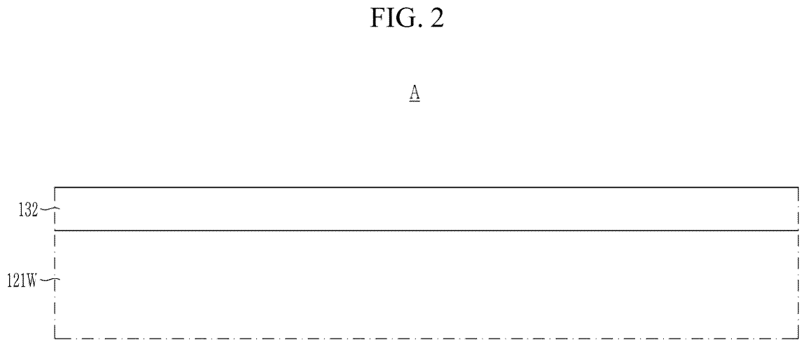

FIG. 2 to FIG. 11 illustrate cross-sectional views for describing a method for manufacturing the semiconductor die stack 100 according to the embodiment of FIG. 1. The method for manufacturing the semiconductor die stack 100 in FIGS. 2 to 11 will be described by enlarging a region A in the semiconductor die stack 100 of the embodiment of FIG. 1. In addition, a method for manufacturing the first semiconductor die 110M and a method for manufacturing the second semiconductor die 110N may be the same, and in FIGS. 2 to 11, the method for manufacturing the semiconductor dies 110 excluding “first”, “second”, “M”, and “N” will be described. In other words, elements described in FIGS. 2 to 11 should be understood as being applicable to both the first semiconductor die 110M and the second semiconductor die 110N.

FIG. 2 illustrates a cross-sectional view showing an operation of depositing a lower dielectric layer 132 on a wafer 121W.

Referring to FIG. 2, the lower dielectric layer 132 may be deposited on a front side structure on a front side of the wafer 121W or on a back side of the wafer 121W. The lower dielectric layer 132 may be deposited continuously and conformally along the wafer 121W. In an embodiment, the lower dielectric layer 132 may include a silicon compound. In an embodiment, the lower dielectric layer 132 may include SiO₂ or SiCN. In an embodiment, the lower dielectric layer 132 may be formed through an atomic layer deposition (ALD) process or a chemical vapor deposition (CVD) process.

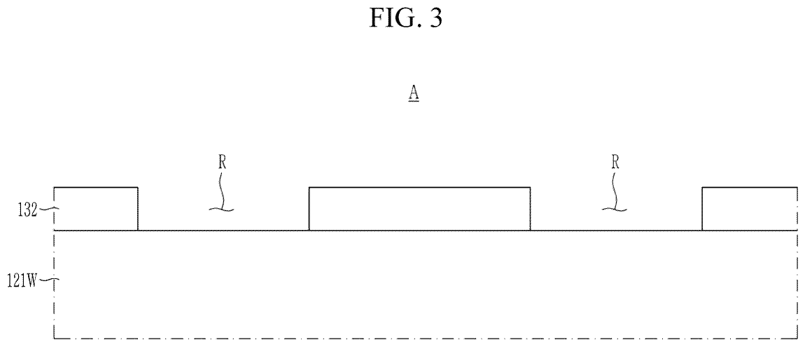

FIG. 3 illustrates a cross-sectional view showing an operation of forming recessed portions R in the lower dielectric layer 132.

Referring to FIG. 3, a photoresist may be applied on the lower dielectric layer 132, and a photoresist pattern may be formed by exposing and developing the photoresist. In an embodiment, the photoresist may be formed by performing a spin coating process. In an embodiment, the photoresist may include an organic polymer resin comprising a photoactive material.

Thereafter, the lower dielectric layer 132 exposed from the photoresist pattern may be etched using the photoresist pattern as an etching mask to form the recessed portions R in the lower dielectric layer 132. In an embodiment, a process of etching the lower dielectric layer 132 may be performed by dry etching.

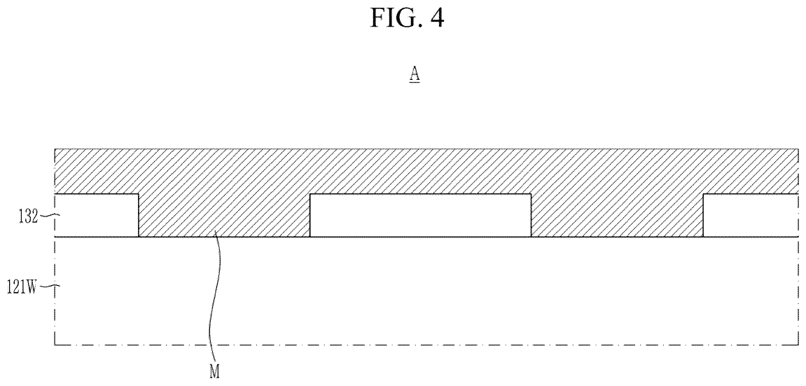

FIG. 4 illustrates a cross-sectional view showing an operation of filling the recesses R with a conductive material M.

Referring to FIG. 4, a barrier layer may be formed on the lower dielectric layer 132. The barrier layer may be formed continuously and conformally along the lower dielectric layer 132 and the recessed portions R formed in the lower dielectric layer 132. The barrier layer may inhibit a conductive material formed in a subsequent process from diffusing into the lower dielectric layer 132 or the dielectric of the front side structure, thereby preventing short circuits between wires. In an embodiment, the barrier layer may include titanium or a titanium alloy. In an embodiment, the barrier layer may be formed through a sputtering process.

Thereafter, a seed metal layer may be disposed on the barrier layer. The seed metal layer may be formed continuously and conformally along the barrier layer. In an embodiment, the seed metal layer may include copper or a copper alloy. In an embodiment, the seed metal layer may be formed by a sputtering or electroless plating process. In an embodiment, a cleaning process or metal catalyst activation pretreatment process may be performed prior to the electroless plating process.

Thereafter, the conductive material M may be positioned on the seed metal layer. In an embodiment, the conductive material M may include copper or a copper alloy. In an embodiment, the conductive material M may be formed by electrolytic plating. The conductive material M may be formed by growing a metal film by electrolytic plating from the seed metal layer formed first. The conductive material M may cover an upper surface of the lower dielectric layer 132 and beyond the upper surface of the lower dielectric layer 132.

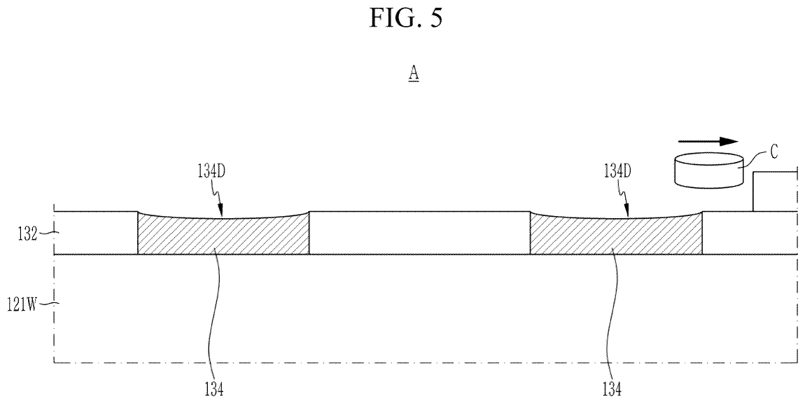

FIG. 5 illustrates a cross-sectional view showing an operation of performing a planarization process on the conductive material M.

Referring to FIG. 5, in order to align a level of an upper surface of the conductive material M with a level of the upper surface of the lower dielectric layer 132, chemical mechanical polishing (CMP) may be performed on the conductive material M covering the upper surface of the lower dielectric layer 132. After performing the CMP process, bonding pads 134 may be formed.

In a process of forming the bonding pads 134 by performing the CMP process, dishing 134D may occur in which a central region of the bonding pad 134 is removed more than a peripheral region of the bonding pad 134 due to a difference in selectivity between film quality of the lower dielectric layer 132 and film quality of the bonding pad 134 and an effect of mechanical processing.

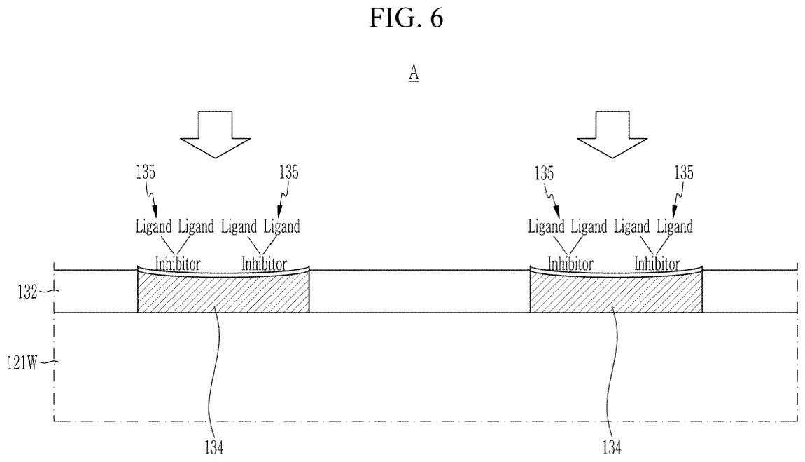

FIG. 6 illustrates a cross-sectional view showing an operation of adsorbing an inhibitor 135 onto the bonding pads 134.

Referring to FIG. 6, the inhibitor 135 may be selectively adsorbed onto the bonding pads 134. The inhibitor 135 may form a barrier layer on the bonding pads 134. The inhibitor 135 may not be adsorbed on the lower dielectric layer 132. In an embodiment, the inhibitor 135 may be formed by a chemical vapor deposition (CVD) process, a spin coating process, or a dipping process. In an embodiment, a vertical thickness of the barrier layer formed by the inhibitor 135 may have a range of about 0.5 nm to about 5 nm.

The inhibitor 135 may be a self-assembled monolayer (SAM). The inhibitor 135 may include a head group, a hydrocarbon chain, and a terminal group (ligand). The inhibitor 135 may include an organic compound as a head group. The head group of the inhibitor 135 may be adsorbed to the bonding pad 134 by covalent bonding and may not be covalently bonded to the lower dielectric layer 132, such that the inhibitor 135 may not be adsorbed to the lower dielectric layer 132.

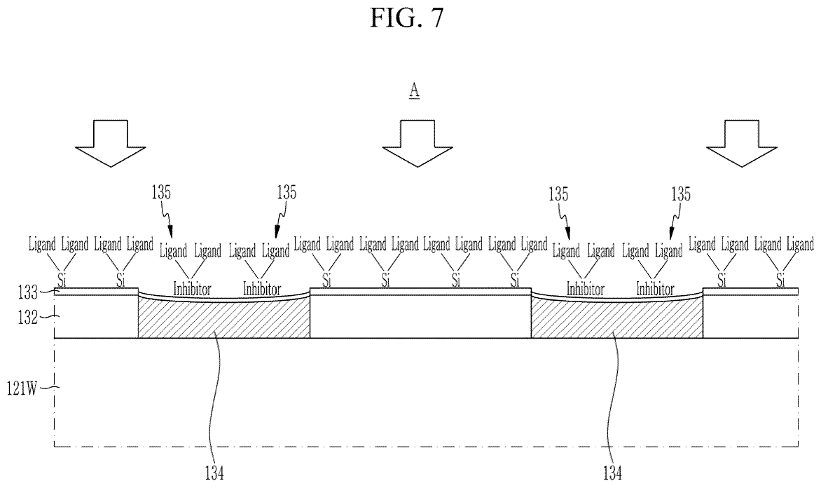

FIG. 7 illustrates a cross-sectional view showing an operation of supplying a silicon compound to the lower dielectric layer 132.

Referring to FIG. 7, the silicon compound may be supplied to a bonding surface of the lower dielectric layer 132. The inhibitor 135 may have a property of repelling the silicon compound, and thus, the inhibitor 135 may barrier the silicon compound from being supplied onto the bonding pads 134, and the silicon compound may be formed only on the lower dielectric layer 132. The silicon compound to be supplied to the bonding surface of the lower dielectric layer 132 may be determined depending on a material of the lower dielectric layer 132. In an embodiment, a source that supplies the silicon compound may include a source of SiHX, SiCXNX, or SiNX series. In an embodiment, a temperature at which the silicon compound is supplied may be less than or equal to about 400° C.

An upper dielectric layer 133 may be disposed on the lower dielectric layer 132 by supplying the silicon compound. The lower dielectric layer 132 and the upper dielectric layer 133 may be collectively referred to as a dielectric layer 131. The upper dielectric layer 133 may have a smaller thickness than a thickness of the lower dielectric layer 132. The silicon compound may be supplied on the surface of the lower dielectric layer 132, and a content per unit volume of silicon, oxygen, carbon, or nitrogen in the upper dielectric layer 133 may be greater than a content per unit volume of silicon, oxygen, carbon, or nitrogen in the lower dielectric layer 132. When the content per unit volume of silicon, oxygen, carbon, or nitrogen in the upper dielectric layer 133 is greater than the content per unit volume of silicon, oxygen, carbon, or nitrogen in the lower dielectric layer 132, a number of reaction sites that react to a plasma activation process may increase, and thus, when performing the hybrid process, the bonding force between the dielectric layers 131 (or the upper dielectric layers 133) may be improved.

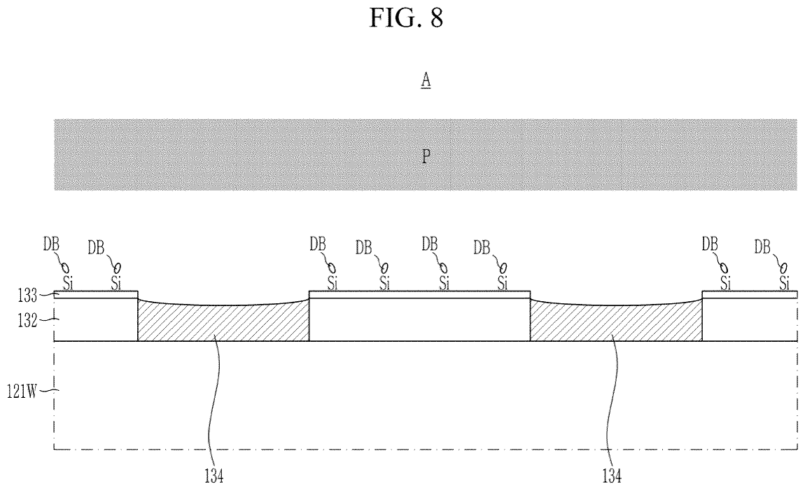

FIG. 8 illustrates a cross-sectional view showing an operation of activating the upper dielectric layer 133 by plasma P.

Referring to FIG. 8, a surface of the upper dielectric layer 133 may activated by the plasma P. In an embodiment, the plasma P may use H₂ (hydrogen) plasma, O₂ (oxygen) plasma, or N₂ (nitrogen) plasma. The plasma P may act to cause silicon atoms on a bonding surface of the upper dielectric layer 133 to have dangling bonds DB. When the silicon compound is additionally supplied to the lower dielectric layer 132 to form the upper dielectric layer 133, a number of dangling bonds DB formed on silicon atoms at the bonding surface of the upper dielectric layer 133 may increase.

During a plasma (P) activation process, the inhibitor 135 formed on the bonding surface of the bonding pad 134 may prevent the bonding surface of the bonding pad 134 from reacting to the plasma P. This may prevent the bonding surface of the bonding pad 134 from reacting with the plasma P to generate contaminants and prevent the contaminants from remaining in a chamber and contaminating the chamber. In addition, it may be possible to prevent the bonding surface of the bonding pad 134 from being oxidized or nitrided by oxygen plasma P or nitrogen plasma P. In this way, the problem of the bonding surface of the bonding pad 134 being oxidized or nitrided, thereby reducing resistivity of the bonding pads 134, may be solved, and restriction on use of the oxygen plasma P or the nitrogen plasma P may be eliminated.

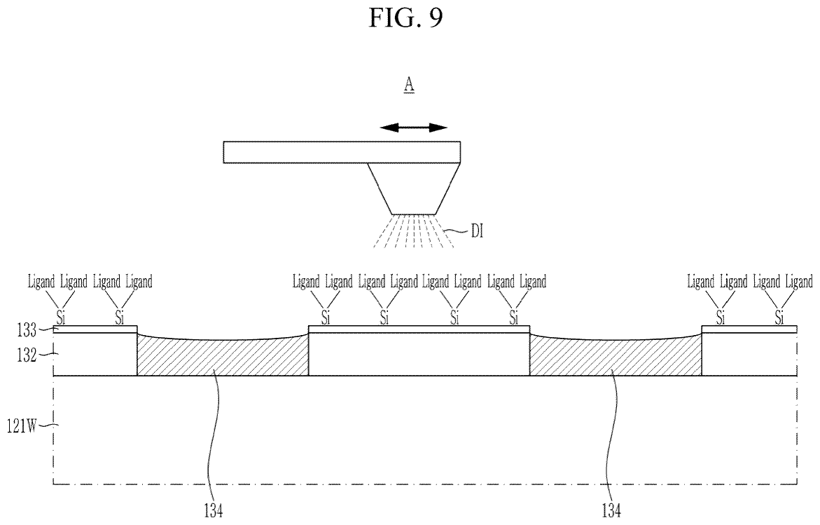

FIG. 9 illustrates a cross-sectional view showing an operation of cleaning a surface of the upper dielectric layer 133.

Referring to FIG. 9, the surface of the plasma-treated upper dielectric layer 133 may be cleaned. In an embodiment, the cleaning process may be performed by deionized (DI) water. When the cleaning process is performed, —OH groups may be bonded to dangling bonds DB formed on silicon atoms of the bonding surface of the upper dielectric layer 133. The inhibitor 135 may be removed through a plasma activation process and a cleaning process.

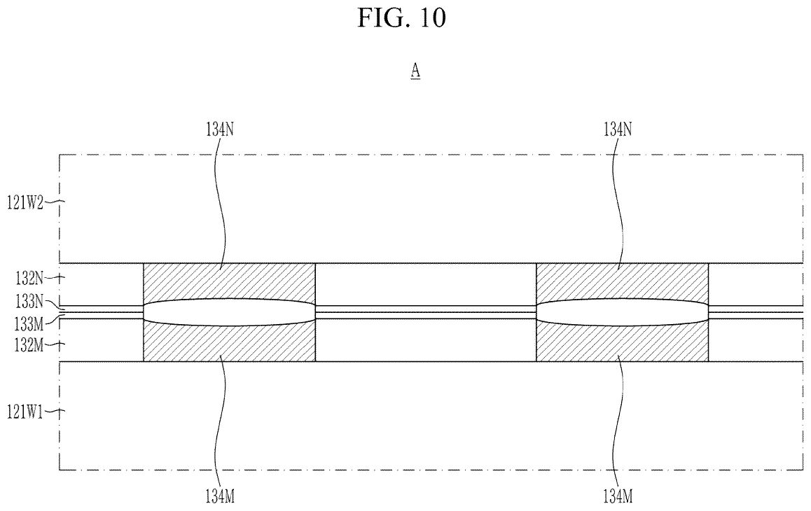

FIG. 10 illustrates a cross-sectional view showing an operation of bonding a first wafer 12W1 and a second wafer 121W2 on which a cleaning process has been performed.

Referring to FIG. 10, the first wafer 12W1 on which the cleaning process has been performed and the second wafer 12W2 on which the cleaning process has been performed may be aligned and pre-bonded. The first dielectric layer 131M of the first wafer 12W1 and the second dielectric layer 131N of the second wafer 12W2 may be in physical contact, and an —OH group on the first dielectric layer 131M and an —OH group on the second dielectric layer 131M may be combined to release water molecules, and the first dielectric layer 131M and the second dielectric layer 131N may be bonded. In this case, the first bonding pads 134M of the first wafer 12W1 and the second bonding pads 134N of the second wafer 12W2 may be in an unbonded state with a gap therebetween.

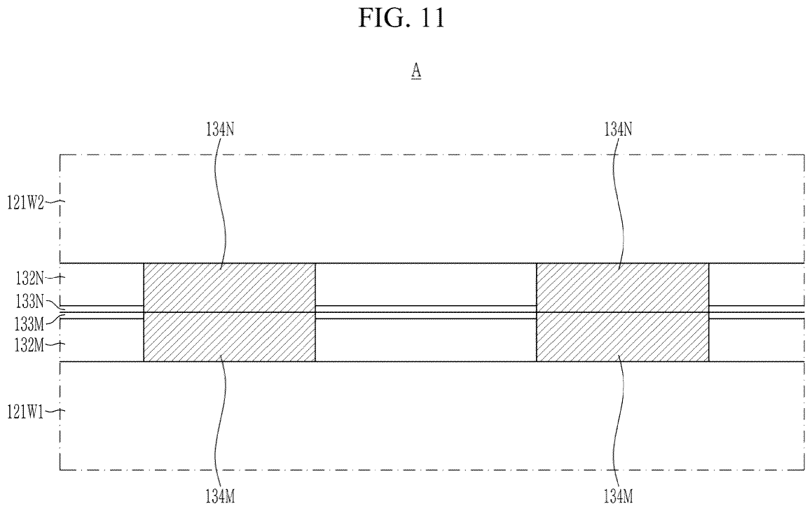

FIG. 11 illustrates a cross-sectional view showing an operation of performing annealing on the bonded first wafer 12W1 and the second wafer 121W2.

Referring to FIG. 11, the annealing process may be performed, and the first bonding pads 134M of the first wafer 12W1 and the second bonding pads 134N of the second wafer 12W2 may be bonded. Due to a difference in coefficient of thermal expansion (CTE) between the dielectric layer 131 and the bonding pads 134, the first bonding pads 134M of the first wafer 12W1 and the second bonding pads 134N of the second wafer 12W2 may expand to fill the dishing 134D (see FIG. 5), and may be bonded to each other while the annealing process is performed. In an embodiment, pressure applied while the annealing process is performed may be less than about 30 MPa. In an embodiment, the annealing process may be performed at a temperature of about 100° C. to about 500° C.

Thereafter, the bonded first wafer 12W1 and the second wafer 121W2 may be singulated to form the semiconductor die stack 100.

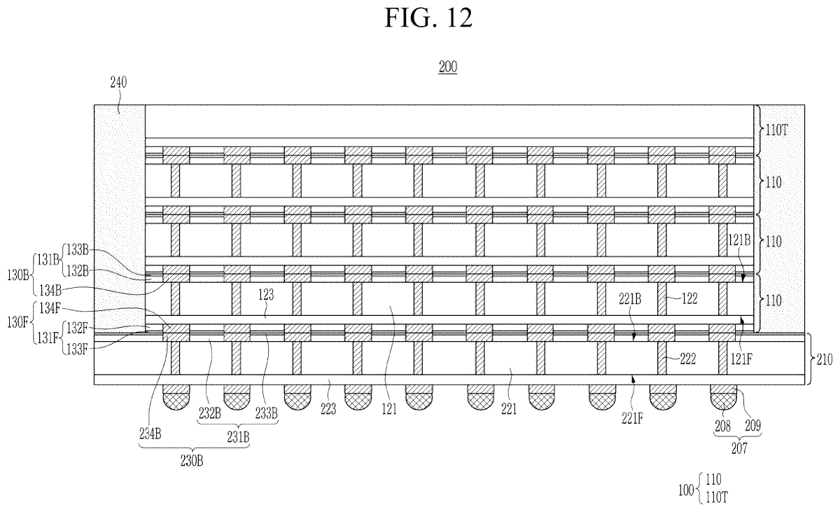

FIG. 12 illustrates a cross-sectional view showing a semiconductor package 200 including the semiconductor die stack 100 of FIG. 1.

Referring to FIG. 12, the semiconductor package 200 may include a base die 210, the semiconductor die stack 100, and a molding material 240. The semiconductor package 200 may include a high bandwidth memory (HBM). The high-bandwidth memory (HBM) may include a high-performance three-dimensional (3D) stacked dynamic random access memory RAM (DRAM). The high-bandwidth memory (HBM) may implement multiple memory channels through a memory stack manufactured by vertically stacking memory dies. Accordingly, the HBM may achieve short latency and high bandwidth compared to related art DRAM products, and may reduce a total area occupied by individual DRAMs on the substrate, which is advantageous in terms of high bandwidth per area and reduced power consumption.

Bump structures 207 may be disposed on or under the base die 210. Each of the bump structures 207 may include a solder 208 and a pillar 209. The bump structures 207 may electrically connect the front side structure 223 of the base die 210 to an external device. In an embodiment, the solder 208 may include at least one of tin, silver, lead, nickel, copper, or any alloy thereof. In an embodiment, the pillar 209 may include at least one of copper, aluminum, tungsten, nickel, gold, tin, titanium, or any alloy thereof.

The base die 210 may be disposed on or under the semiconductor die stack 100. The base die 210 may include a buffer die. When exchanging data between devices with different data processing speeds, processing units, and usage times, data loss may occur due to differences in data processing speeds, processing units, and usage times between devices. To prevent such loss, the base die 210 may be disposed between the semiconductor die stack 100 and the external device, and when data is exchanged between the semiconductor die stack 100 and the external device, information may be temporarily stored in the base die 210. When transmitting data to the semiconductor dies 110 of the semiconductor die stack 100 and/or receiving data from the semiconductor dies 110 of the semiconductor die stack 100, the base die 210 may sequentially pass the data after aligning an order of the data.

The base die 210 may include a die base 221, through silicon vias 222, a front side structure 223, and a back side bonding structure 230B.

The die base 221 may be disposed such that a front side 221F thereof faces the bump structures 207. The die base 221 may be a die formed from a wafer. In an embodiment, the die base 221 may include silicon or other semiconductor materials. The through-silicon vias 222 may be disposed within the die base 221. Each of the through silicon vias 222 may be positioned between an active layer or a wiring layer of the front side structure 223 and each of the bonding pads 234B of the back side bonding structure 230B, and may electrically connect them. In an embodiment, the through silicon vias 222 may include at least one of tungsten, aluminum, copper, or any alloy thereof. The front side structure 223 may be disposed between the die base 221 and the bump structures 207.

The back side bonding structure 230B may be disposed on a back side 221B of the die base 221. The back side bonding structure 230B may include a back side dielectric layer 231B and back side bonding pads 234B.

The back side dielectric layer 231B may include a back side lower dielectric layer 232B and a back side upper dielectric layer 233B. The back side dielectric layer 231B may be bonded to a front side dielectric layer 131F of the semiconductor die 110 positioned at a lowest position of the semiconductor die stack 100. For example, the back side dielectric layer 231B may be directly bonded to the front side dielectric layer 131F of the semiconductor die 110 positioned at the lowest position of the semiconductor die stack 100. The front side dielectric layer 131F may include a front side lower dielectric layer 132F and a front side upper dielectric layer 133F. A silicon content per unit volume in the back side upper dielectric layer 233B of the base die 210 may be higher than a silicon content per unit volume in the back side lower dielectric layer 232B of the base die 210, and a silicon content per unit volume in the front side upper dielectric layer 133F of the semiconductor die 110 may be higher than a silicon content per unit volume in the front side lower dielectric layer 132F of the semiconductor die 110 such the back side lower dielectric layer 232B of the base die 210 and the front side upper dielectric layer 133F of the semiconductor die 110 may be bonded with a high bonding strength.

Each of the back side bonding pads 234B may be bonded (e.g., directly bonded) to a corresponding front side bonding pad 134F of the front side bonding pads 134F of the semiconductor die 110 positioned at a lowest position of the semiconductor die stack 100. Each bonding surface among the back side bonding pads 234B of the base die 210 and each bonding surface among the front side bonding pads 134F of the semiconductor die 110 may not be nitrided or oxidized, and thus, electrical characteristics between each of the back side bonding pads 234B and the corresponding front side bonding pad 134F among the front side bonding pads 134F may be improved, and resistivity therebetween may be reduced.

The semiconductor die stack 100 may be disposed on the base die 210. The semiconductor die stack 100 may include a plurality of semiconductor dies 110. In an embodiment, the semiconductor dies 110 may include a memory die. FIG. 12 illustrates a semiconductor die stack 100 including four semiconductor dies 110, but the present disclosure is not limited thereto, and a semiconductor die stack 100 including more than four semiconductor dies 110 may be included within the scope of the present disclosure. Specifically, the semiconductor dies 110 may include 8, 12, 16, 20, or 24 semiconductor dies. Each of the semiconductor dies 110 may include the die base 121, through silicon vias 122, a front side structure 123, a front side bonding structure 130F, and a back side bonding structure 130B. A semiconductor die 110T positioned at an uppermost portion among the semiconductor dies 110 may include the die base 121, the front side structure 123, and the front side bonding structure 130F.

The die base 121 may be disposed such that a front side 121F thereof faces the base die 210. The through-silicon vias 122 may be disposed within the die base 121. Each of the through silicon vias 122 may be positioned between an active layer or a wiring layer of the front side structure 123 and each of bonding pads 134B of the back side bonding structure 130B, and may electrically connect them. In an embodiment, the through silicon vias 122 may include at least one of tungsten, aluminum, copper, or any alloy thereof. The front side structure 123 may be disposed between the die base 121 and the front side bonding structure 130F.

The front side bonding structure 130F may be disposed on the front side 121F of the die base 121. The front side bonding structure 130F may include the front side dielectric layer 131F and the front side bonding pads 134F. The front side dielectric layer 131F may include the front side lower dielectric layer 132F and the front side upper dielectric layer 133F. The back side bonding structure 130B may be disposed on a back side 121B of the die base 121. The back side bonding structure 130B may include a back side dielectric layer 131B and the back side bonding pads 134B. The back side dielectric layer 131B may include a back side lower dielectric layer 132B and a back side upper dielectric layer 133B.

The back side dielectric layer 131B of each semiconductor die 110 among the semiconductor dies 110 may be bonded (e.g., directly bonded) to the front side dielectric layer 131F of a neighboring semiconductor die 110. A silicon content per unit volume in the back side upper dielectric layer 133B of each semiconductor die 110 may be higher than a silicon content per unit volume in the back side lower dielectric layer 132B of each semiconductor die 110, and a silicon content per unit volume in the front side upper dielectric layer 133F of the neighboring semiconductor die 110 may be higher than a silicon content per unit volume in the front side lower dielectric layer 132F of the neighboring semiconductor die 110, and thus, the back side lower dielectric layer 232B of each semiconductor die 110 and the front side upper dielectric layer 133F of the neighboring semiconductor die 110 may be bonded with a high bonding strength.

Each of the back side bonding pads 134B of each semiconductor die 110 among the semiconductor dies 110 may be bonded (e.g., directly bonded) to a corresponding front side bonding pad 134F among the front side bonding pads 134F of a neighboring semiconductor die 110. Each bonding surface among the back side bonding pads 134B of each semiconductor die 110 and each bonding surface among the front side bonding pads 134F of the neighboring semiconductor die 110 may not be nitrided or oxidized, and thus, each of the back side bonding pads 134B and the corresponding front side bonding pad 134F among the front side bonding pads 134F bonded to each other may have improved electrical characteristics and reduced resistivity.

The molding material 240 may cover the semiconductor die stack 100 on the base die 210. The molding material 240 may cover side surfaces of the semiconductor die stack 100 on the base die 210. An upper surface of the semiconductor die stack 100 may be exposed to an outside from the molding material 240. In an embodiment, the molding material 240 may include an epoxy molding compound (EMC).

According to one or more example embodiments of the disclosure, during a plasma activation process in a hybrid bonding process, an inhibitor may be formed on a bonding surface of a metal such that the bonding surface of the metal is not affected by plasma.

According to one or more example embodiments of the disclosure, by supplying a dielectric source onto a bonding surface of a dielectric, a number of reaction sites that react to the plasma activation process on the bonding surface of the dielectric may be increased.

According to one or more example embodiments of the disclosure, a silicon compound source may be supplied onto a bonding surface of a dielectric layer including a silicon compound to form a lower dielectric layer and an upper dielectric layer. The upper dielectric layer may have a higher silicon content than that of the lower dielectric layer, and therefore, a number of reactive sites that react to the plasma activation process may increase, which may enhance a bonding strength between the dielectric layers.

According to one or more example embodiments of the disclosure, the inhibitor may be formed on the bonding surface of the metal, and therefore, the bonding surface of the metal may not be affected by the plasma while the plasma process is performed. This may prevent the chamber from becoming contaminated with metal.

According to one or more example embodiments of the disclosure, the inhibitor may be formed on the bonding surface of the metal to prevent the bonding surface of the metal from being oxidized or nitrided by the plasma, thereby removing restrictions on the plasma source used during the hybrid bonding process.

While this disclosure has been described in connection with example embodiments, it is to be understood that the disclosure is not limited to these embodiments, but, on the contrary, is intended to cover various modifications and equivalent arrangements included within the spirit and scope of the appended claims and their equivalents.

What is claimed is:

1. A semiconductor die stack comprising:
a first semiconductor die comprising a first die base and a first bonding structure on the first die base, wherein the first bonding structure comprises:
a first dielectric layer comprising a first lower dielectric layer and a first upper dielectric layer on the first lower dielectric layer, and comprising a silicon compound; and
a plurality of first bonding pads extending through the first dielectric layer,
wherein the first lower dielectric layer comprises a first content of silicon per unit volume,
wherein the first upper dielectric layer comprises a second content of silicon per unit volume, the second content per unit volume being greater than the first content per unit volume; and
a second semiconductor die comprising a second die base and a second bonding structure on the second die base, wherein the second bonding structure comprises:
a second dielectric layer comprising a second lower dielectric layer and a second upper dielectric layer on the second lower dielectric layer, and comprising a silicon compound; and
a plurality of second bonding pads extending through the second dielectric layer,
wherein the second lower dielectric layer comprises a third content of silicon per unit volume,
wherein the second upper dielectric layer comprises a fourth content of silicon per unit volume, the fourth content per unit volume being greater than the third content per unit volume,
wherein the first dielectric layer is bonded to the second dielectric layer, and
wherein each first bonding pad among the plurality of first bonding pads is bonded to a corresponding second bonding pad among the plurality of second bonding pads.

2. The semiconductor die stack of claim 1, wherein the silicon compound comprises SiCN.

3. The semiconductor die stack of claim 2, wherein a carbon content per unit volume of the first upper dielectric layer is greater than a carbon content per unit volume of the first lower dielectric layer, and
wherein a carbon content per unit volume of the second upper dielectric layer is greater than a carbon content per unit volume of the second lower dielectric layer.

4. The semiconductor die stack of claim 2, wherein a nitrogen content per unit volume of the first upper dielectric layer is greater than a nitrogen content per unit volume of the first lower dielectric layer, and
wherein a nitrogen content per unit volume of the second upper dielectric layer is greater than a nitrogen content per unit volume of the second lower dielectric layer.

5. The semiconductor die stack of claim 2, wherein an oxygen content per unit volume of the first upper dielectric layer is greater than an oxygen content per unit volume of the first lower dielectric layer, and
wherein an oxygen content per unit volume of the second upper dielectric layer is greater than an oxygen content per unit volume of the second lower dielectric layer.

6. The semiconductor die stack of claim 1, wherein the silicon compound comprises SiO₂.

7. The semiconductor die stack of claim 6, wherein an oxygen content per unit volume of the first upper dielectric layer is greater than an oxygen content per unit volume of the first lower dielectric layer, and
wherein an oxygen content per unit volume of the second upper dielectric layer is greater than an oxygen content per unit volume of the second lower dielectric layer.

8. The semiconductor die stack of claim 1, wherein the first lower dielectric layer has a first thickness,
wherein the first upper dielectric layer has a second thickness that is smaller than the first thickness,
wherein the second lower dielectric layer has a third thickness, and
wherein the second upper dielectric layer has a fourth thickness that is smaller than the third thickness.

9. The semiconductor die stack of claim 8, wherein each of the second thickness and the fourth thickness is in a range of about 0.5 nm to about 5 nm.

10. A semiconductor package comprising:
a base die;
a semiconductor die stack comprising a plurality of semiconductor dies vertically stacked on the base die; and
a molding material on at least one surface of the semiconductor die stack on the base die,
wherein each of the plurality of semiconductor dies comprises:
a die base comprising a front side and a back side;
a front side bonding structure disposed on the front side of the die base, the front side bonding structure comprising a front side dielectric layer comprising a silicon compound, and a plurality of front side bonding pads extending through the front side dielectric layer; and
a back side bonding structure disposed on the back side of the die base, the back side bonding structure comprising a back side dielectric layer comprising the silicon compound, and a plurality of back side bonding pads extending through the back side dielectric layer,
wherein each of the front side dielectric layer and the back side dielectric layer comprises:
a lower dielectric layer comprising a first content of silicon per unit volume; and
an upper dielectric layer comprising a second content per unit volume of silicon that is greater than the first content per unit volume,
wherein a front side dielectric layer of each semiconductor die among the plurality of semiconductor dies is bonded to a back side dielectric layer of a neighboring semiconductor die, and
wherein each front side bonding pad among a plurality of front side bonding pads of each semiconductor die among the plurality of semiconductor dies is bonded to a corresponding back side bonding pad among a plurality of back side bonding pads of a neighboring semiconductor die.

11. The semiconductor package of claim 10, wherein the plurality of semiconductor dies comprise a memory die.

12. The semiconductor package of claim 10, wherein the base die comprises a buffer die.

13. A method for manufacturing a semiconductor die stack, the method comprising:
depositing a first lower dielectric layer comprising a silicon compound on a first wafer, and depositing a second lower dielectric layer comprising a silicon compound on a second wafer;
forming a plurality of first bonding pads in the first lower dielectric layer and forming a plurality of second bonding pads in the second lower dielectric layer;
adsorbing an inhibitor on the plurality of first bonding pads and on the plurality of second bonding pads;
forming a first upper dielectric layer by supplying a silicon compound to the first lower dielectric layer and forming a second upper dielectric layer by supplying a silicon compound to the second lower dielectric layer, wherein the first lower dielectric layer comprises a first content of silicon per unit volume, the first upper dielectric layer comprises a second content of silicon per unit volume that is greater than the first content per unit volume, the second lower dielectric layer comprises a third content of silicon per unit volume, and the second upper dielectric layer comprises a fourth content of silicon per unit volume that is greater than the third content per unit volume;
activating a surface of the first upper dielectric layer by plasma, and activating a surface of the second upper dielectric layer by plasma;
cleaning the surface of the first upper dielectric layer and cleaning the surface of the second upper dielectric layer; and
bonding the first upper dielectric layer of the first wafer and the second upper dielectric layer of the second wafer.

14. The method of claim 13, wherein the adsorbing the inhibitor is performed by a chemical vapor deposition (CVD) process, a spin coating process, or a dipping process.

15. The method of claim 13, wherein, in the supplying of the silicon compound to the first lower dielectric layer and the supplying of the silicon compound to the second lower dielectric layer, the inhibitor barriers the silicon compound from being supplied onto the plurality of first bonding pads and onto the plurality of second bonding pads.

16. The method of claim 13, wherein the plasma comprises hydrogen plasma, oxygen plasma, or nitrogen plasma.

17. The method of claim 13, wherein in the activating of the surface of the first upper dielectric layer by the plasma and activating the surface of the second upper dielectric layer by the plasma, the inhibitor barriers the plurality of first bonding pads and the plurality of second bonding pads from reacting with the plasma.

18. The method of claim 13, wherein the inhibitor is removed through the activating by the plasma and the cleaning.

19. The method of claim 13, further comprising:
annealing the bonded first and second wafers after the bonding of the first upper dielectric layer of the first wafer and the second upper dielectric layer of the second wafer.

20. The method of claim 13, wherein in the adsorbing of the inhibitor on the plurality of first bonding pads and on the plurality of second bonding pads, the inhibitor forms a first barrier layer on the plurality of first bonding pads and forms a second barrier layer on the plurality of second bonding pads.
